(19) United States
(12) Patent Application Publication
(10) Pub. No.: US 2020/0049131 A1
(43) Pub. Date: Feb. 13, 2020

(54) TEST METHOD FOR TESTING THE BEHAVIOR OF A WIND FARM IN RESPONSE TO AN UNDERFREQUENCY EVENT

(71) Applicant: Wobben Properties GmbH, Aurich (DE)

(72) Inventors: Wolfgang DE BOER, Moormerland (DE); Kai BUSKER, Großefehn (DE); Sönke ENGELKEN, Bremen (DE)

(21) Appl. No.: 16/494,210

(22) PCT Filed: Mar. 9, 2018
(86) PCT No.: PCT/EP2018/055954

§ 371 Date: Sep. 13, 2019

(30) Foreign Application Priority Data
Mar. 14, 2017 (DE) 10 2017 105 367.0

(51) Int. Cl. F03D 17/00; H02J 3/24; H02J 3/38; G01R 31/40; G05B 23/02

(52) U.S. Cl. CPC F03D 17/00; H02J 3/24; G05B 23/0256; G01R 31/40; H02J 3/386

(57) ABSTRACT

A test method for testing a behavior of a wind farm in response to a frequency event is provided. The wind farm has wind power plants, which supply electrical power to a grid which has a grid voltage and with a grid frequency. Each plant has a frequency mode in which the supplied power is temporarily modified per the grid frequency if a frequency event occurs. In a farm testing mode, if a frequency event occurs, each plant changes its frequency mode and the frequency modes are simultaneously tested to test the behavior of the farm. Each frequency mode uses a test frequency function emulating a frequency event, instead of a measured frequency, and the frequency modes are coordinated such that the plants controlled by a common time start command, start their frequency modes simultaneously, and an identical test frequency function is defined for each of the plants.

### BACKGROUND

### Technical Field

The present invention relates to a test method for testing a behavior of a wind farm in response to an underfrequency event. The present invention also relates to a wind farm having a plurality of wind power installations, which wind farm is configured to execute a test method of said kind. The invention further relates to wind power installations of a wind farm of said kind.

### Description of the Related Art

It is known in the case of wind power installations which feed electrical power into an electrical supply grid to also perform support tasks for supporting the electrical supply grid. A support task of said kind involves temporarily feeding more power into the electrical supply grid, specifically more power than can currently be drawn from the wind, in the case of an underfrequency in the electrical supply grid. Rotational energy from the rotor of the respective wind power installation can be used for this purpose. The rotor is therefore braked and the power drawn in this way can be fed into the electrical supply grid as additional power. This functionality can be tripped by way of the wind power installation in question monitoring the frequency of the electrical supply grid, that is to say the grid frequency, and beginning to generate additional power from the rotation of the rotor when said frequency drops below a predetermined value.

In order to test a functionality of said kind, a virtual frequency, instead of the grid frequency which is actually measured, can be prespecified to the corresponding controller of the wind power installation. Therefore, for example, a frequency profile is artificially prespecified over a short time period and input into the controller as the actual grid frequency. The controller then reacts to this virtual frequency profile as if it were the actual frequency profile of the grid frequency, not least in respect of a power prespecification. Depending on this virtual frequency profile, the wind power installation therefore then generates additional power from the rotational energy of the wind power installation and feeds said additional power into the electrical supply grid. With knowledge of this virtual frequency profile, it is then particularly possible to also check the change in the fed-in electrical power and in so doing it is also possible to record how the wind power installation actually behaves in response to an underfrequency event of said kind.

In the case of a wind farm, the described support in an underfrequency situation takes place simply by way of each wind power installation of the wind farm reacting independently to the underfrequency event and temporarily increasing its power independently. To this end, each wind power installation independently monitors the frequency and carries out the above-described support. In this way, the wind farm then carries out support by way of the sum of all increases in power of the wind power installations of the wind farm overall.

In order to test a behavior of said kind of the wind farm, a virtual frequency profile would also have to be prespecified here. However, the actual grid frequency should not or must not be artificially moved to this underfrequency situation.

In order to test said functionality of the wind farm, the corresponding functionality of each individual wind power installation therefore has to be tested. However, a realistic result can only be expected when all of the wind power installations react to the same underfrequency event simultaneously, that is to say when the same frequency is also synchronously used as the basis.

The German Patent and Trade Mark Office has searched the following prior art in the priority application to the present application: DE 10 2008 049 629 A1 and DE 10 2015 201 857 A1.

### BRIEF SUMMARY

A test method for a frequency event, in particular an underfrequency event for a wind farm, is provided. The test method provides results which are as realistic as possible.

A test method is provided to test a behavior of a wind farm in response to a frequency event. In this case, a frequency event is a situation in the electrical supply grid in the case of which the grid frequency leaves a normal range, particularly drops too sharply or rises too sharply. Absolute values, but also relative values, can be exceeded in the process. A particularly important case is that of testing an underfrequency event in which the grid frequency drops too sharply. A wind farm of said kind has a plurality of wind power installations which feed electrical power into an electrical supply grid. A wind farm usually feeds power into the electrical supply grid via a common grid connection point. However, it is also possible for a wind farm of appropriate size to have a plurality of smaller wind farms which are jointly controlled via a superordinate central farm controller and, in so doing, feed power into the electrical supply grid via different connection points. A large wind farm of said kind can also be understood to mean a wind farm here and can be tested using the proposed test method.

Each wind power installation has a rotor with one or more rotor blades, usually specifically a rotor with three rotor blades with which wind power is generated from wind and fed into the electrical supply grid. Therefore, here, the wind power defines that power which can currently be drawn from the prevailing wind and fed into the electrical supply grid.

For the purpose of describing the present invention, losses can be ignored here.

The electrical supply grid has a grid voltage with a grid frequency, as is also generally customary. Therefore, the grid frequency defines that frequency which the grid voltage respectively currently exhibits. In the ideal case, the grid frequency corresponds to a rated grid frequency, for example 50 Hz in the synchronous grid of Continental Europe or 60 Hz in the US grid, but can also differ therefrom. An underfrequency event is one in which the grid frequency drops significantly below the rated grid frequency. This can be the case, for example, even at 0.3 percent of the grid frequency below the rated grid frequency.

The wind power installations of the wind farm each have a frequency mode which is referred to as the underfrequency mode in an underfrequency situation. This frequency mode describes a mode in which the fed-in power is temporarily changed depending on the grid frequency when a frequency event occurs. At this moment of the frequency event, which moment usually does not last for long, a power other than the wind power is fed in, that is to say a power other than the power which can be drawn from the wind at that moment. This may be more, but also less, power.

One possible frequency mode can make provision for the wind farm to, at least temporarily, reduce power, which is fed into the electrical supply grid, when an overfrequency occurs. A reduction of said kind is performed by the wind power installations and the proposed test method can be used for testing purposes for the entire farm functionality.

For the special case of the underfrequency mode, this describes a mode which temporarily feeds electrical power from rotational energy of the rotor, which electrical power is additional to the wind power, into the electrical supply grid depending on the grid frequency when an underfrequency event occurs. Therefore, in this underfrequency mode, an underfrequency event is detected, or the underfrequency event trips this underfrequency mode. Power is then drawn from rotational energy of the rotor, that is to say the rotor is braked, and this power is fed into the electrical supply grid in addition to the wind power. Therefore, more power than could be drawn from the wind in a normal operating mode and fed into the electrical supply grid at that moment is fed in here.

In principle, each of the wind power installations of the wind farm has a functionality of said kind, that is to say has a frequency mode, in particular an underfrequency mode, to which it can optionally change. However, particularly in the case of mixed farms which have different wind power installations, the situation of not all wind power installations having this functionality may also occur in principle. In this case, any description of the wind power installations of the wind farm relates only to those wind power installations which have a frequency mode or underfrequency mode of said kind and participate in a corresponding network support operation. Accordingly, the description for testing a frequency mode or underfrequency mode of said kind at the farm level also relates only to the wind power installations which participate in this test. In the text which follows, these wind power installations can also be called wind power installations participating in the test or simply participating wind power installations.

A farm test mode is now proposed, which farm test mode is provided for testing a behavior of the wind farm in the case of a frequency event, particularly an underfrequency event. In this farm test mode, the wind power installations each change to their frequency mode or underfrequency mode. To this end, it is now further proposed that the frequency modes or underfrequency modes of the wind power installations participating in the test are tested at the same time in order to test the behavior of the wind farm in this way. This simultaneous testing is therefore part of the farm test mode.

For this test, a test frequency function which emulates a frequency event or an underfrequency event is used instead of a measured frequency in each case, that is to say for each of the participating wind power installations. Therefore, in this case, the participating wind power installations are no longer or no longer completely controlled by the measured grid frequency, but rather by the emulated frequency event or underfrequency event of the test frequency function.

It is now proposed that the frequency modes or underfrequency modes of all participating wind power installations are coordinated by way of the participating wind power installations starting their frequency mode simultaneously in a manner controlled by a common time start command, in particular by way of said participating wind power installations receiving a common start signal simultaneously. An identical test frequency function is also prespecified for each of the wind power installations. Therefore, each wind power installation then uses the same test frequency function and it is ensured that all participating wind power installations start synchronously. The participating wind power installations therefore receive a common time start command in order to start simultaneously as a result. Said wind power installations can receive a synchronously transmitted tripping (or triggering) command as time start command for this purpose. The tripping command is therefore transmitted synchronously and all participating wind power installations receive said command at the same time and immediately start the test. It goes without saying that provision can also be made for all wind power installations to start simultaneously only after a predetermined delay time which is identical for all said wind power installations. As an alternative, it is also possible for the time start command to contain a precise start time and for all participating wind power installations to have a precise clock or precisely know the current time in some other way. To this end, it is possible, for example, for said wind power installations to receive an external time signal, for example as part of a GPS signal, and to be very precisely synchronized in respect of time in this way.

Therefore, a situation is achieved in which the same test frequency function is used for each wind power installation. Therefore, each wind power installation is based on the same test frequency function and it is only necessary to ensure that all participating wind power installations also run through this test frequency function synchronously. To this end, it suffices for all wind power installations to be based on the same frequency function and for a time-synchronous start signal to be present. Therefore, at best, the transmission of a time-synchronous start signal is time-critical, or another precise synchronization of the wind power installations is used. The test frequency function can have been transmitted in advance or, for example, can have already been stored in the wind power installation in advance.

Therefore, it is preferably also proposed that the test frequency function is stored in each wind power installation. The common test and therefore the farm test mode can then be carried out in a simple manner by way of only one common start signal needing to be transmitted to all participating wind power installations simultaneously.

According to one embodiment, it is proposed that a plurality of different test frequency functions are stored in each participating wind power installation. In this case, the same test frequency functions are stored in the participating wind power installations in each case. The test frequency functions which are stored in one wind power installation are therefore also each stored in the other participating wind power installations.

In the farm test mode, it is then proposed to select one test frequency function from amongst the plurality of different test frequency functions. In this case, the same test frequency function is selected in each participating wind power installation, so that all participating wind power installations form the same frequency function for the test.

Therefore, it is possible to not only create a farm test mode but also test different frequency profiles in a simple manner and particularly without a need for a large transmission bandwidth.

In the farm test mode, for starting the test, a selection signal is preferably transmitted to each participating wind power installation for selecting a test frequency function, wherein each wind power installation receives the same selection signal in order to select the same test frequency function. As an alternative, different selections signals can also be used, but provided that they lead to the same test frequency function being selected on each participating wind power installation.

A tripping command is also synchronously transmitted in order to trigger the underfrequency mode of each participating wind power installation. The selection signal and the tripping command are preferably combined in the start signal. In each case, it is necessary to synchronously transmit only these two values to all wind power installations so that said wind power installations run through the same test frequency function for testing their frequency mode or underfrequency mode. As an alternative, the selection signal does not need to be synchronously transmitted, but rather can also be transmitted in advance in order to achieve the selection of the corresponding test frequency function in advance. However, since both the selection signal and the tripping command require only few bits of data, both signals, that is to say the selection signal and the tripping command, can be readily synchronously transmitted together to all participating wind power installations.

According to one embodiment, it is proposed that each test frequency function specifies a frequency profile over a predeterminable profile duration. For example, for testing an underfrequency event for a profile duration of 10 seconds, a frequency profile which, in the first second, drops from the rated frequency to a lower frequency value of, for example, 99 percent of the rated frequency and from there continuously rises to the grid frequency again until the end value of the profile duration of 10 seconds is specified. This is to be understood merely as a simplified example for explanatory purposes.

Furthermore, it is proposed for this embodiment that each wind power installation, in its underfrequency mode, generates an increase in power depending on a frequency, wherein said frequency profile of the test frequency function, instead of the measured frequency, is used for testing the underfrequency mode. In said example, this means that this frequency profile, instead of the measured grid frequency, is used as the basis for the predetermined profile duration of 10 seconds.

It is optionally proposed that the profile duration can be set in order to extend or to compress the test frequency function or its frequency profile in this way. Based on said simplified example, the profile duration of 10 seconds could be changed to 20 seconds. Therefore, the frequency profile mentioned by way of example would then drop from the rated frequency to the smallest frequency value of 99 percent of the rated frequency in the first two seconds and then rise to the rated frequency again over the remaining 18 seconds until the value of 20 seconds. The basic frequency profile, that is to say particularly the characteristics of the selected frequency profile, therefore remains the same, but is extended from 10 seconds to 20 seconds. Similarly, other times can be selected, such as also a smaller profile duration in order to compress the frequency profile in this way.

According to one embodiment, it is proposed for this purpose that the profile duration T_{V} is subdivided into a plurality of identical sampling time steps, with a step duration T_{K}, which identifies the duration of each sampling time step, and a step number k, which indicates the number of sampling time steps of the profile duration T_{V}, so that the profile duration T_{V} can be set by setting the step duration T_{K}. In particular, the formula T_{V}=k*T_{K} holds true, and the test frequency function or the frequency profile has a frequency value for each sampling time step. These frequency values therefore have the step duration as a time interval in relation to one another. Therefore, in the specific implementation, a frequency value can be stored for each sampling time step and these frequency values are gradually called up in the time interval of the step duration.

The step duration is now increased or reduced to extend or compress the frequency curve in respect of time. The frequency values are then called up correspondingly more seldom or more frequently, wherein the number thereof, specifically the step number, remains the same. The frequency curve is then constructed with the same frequency values, but over a longer or shorter time.

The extension or compression of the frequency profile can be achieved indirectly by a prespecified time step, that is to say by prespecifying the step duration, in this way. The frequency profile which is stored in the wind power installation is discretely resolved with respect to time for this purpose and consists, for example, of 100 values for a preset profile duration of 10 seconds. However, these 100 values can be checked with different time steps, wherein the assumed frequency value is preferably kept constant between two checking times. According to one embodiment, it is proposed that the step duration of the sampling time step for the checking times is preset to a value of approximately 100 ms, and/or can be set or varied in a range of from 10 ms to 1000 ms, particular in 10 ms steps.

In principle, it is proposed that, in the farm test mode, the profile duration of each participating wind power installation is set to an identical value, so that, in spite of the change in the profile duration, all wind power installations perform the same change and therefore, as a result, the same test frequency function once again, that is to say are based on the same frequency profile. An item of information for changing or setting the profile duration is preferably transmitted with the start signal.

According to a further embodiment, it is proposed that an amplitude factor is prespecified in order to set the amplitude of the test frequency function or in order to set the amplitude of the frequency profile in order to set the test frequency function or its frequency profile in respect of the amplitude. A stored test frequency function can also be varied in a simple manner and with only little data complexity in this way.

To this end, in the farm test mode, the amplitude factor should be set to an identical value in each participating wind power installation. It is preferably proposed to also set this amplitude factor using the start signal. Therefore, a variation in the amplitude of the emulated frequency can also be performed in a simple manner. The changing or setting of the profile duration is preferably combined with the changing or setting of the amplitude factor.

A selection signal which selects a test frequency function is transmitted in the start signal or in some other way to each wind power installation for the farm test mode, as is a profile duration or an adjustment factor for adjusting the profile duration in order to set the test frequency function or its frequency profile in respect of its time expansion, that is to say possibly to extend or to compress said test frequency function or its frequency profile, and the amplitude factor is transmitted in order to also set the amplitude of the test frequency function or its frequency profile as a result. In this way, a frequency profile can be selected in a simple manner and also further set in respect of its time frame and its amplitude. Finally, the tripping command is still synchronously transmitted to all participating wind power installations and all participating wind power installations then synchronously carry out a frequency or underfrequency mode.

In addition, only a small data set needs to be transmitted overall for these four values and, moreover, only a one-off transmission operation and no permanent transmission is required here. The data, apart from the tripping command, can optionally have already been transmitted in advance, so that only the tripping command then still has to be synchronously transmitted to all participating wind power installations.

According to one embodiment, it is proposed that the wind power installation, when an underfrequency event occurs, feeds additional electrical power from rotational energy of the rotor into the electrical supply grid when the grid frequency falls short of a predetermined frequency value. To this end, it is further proposed that the additional electrical power from rotational energy of the rotor is controlled depending on the further profile of the grid frequency. In this case, a control prespecification is stored in the wind power installation for controlling the additional power from rotational energy of the rotor depending on the further profile of the grid frequency. This control prespecification indicates the level to which the additional electrical power should be fed in depending on the detected frequency. To this end, further information is optionally taken into account, in particular the rotation speed of the rotor of the wind power installation and/or a time period since the beginning of the underfrequency event and/or whether an underfrequency event has already been present within a predetermined time period before the current underfrequency event and the wind power installation has already been operated in the underfrequency mode.

It is preferably proposed that the underfrequency mode is in each case automatically tripped by the wind power installation as soon as the grid frequency falls short of the predetermined frequency value. Therefore, in this respect, only the frequency is taken into account and the behavior of the frequency alone trips the underfrequency mode. Instead of falling short of a predetermined frequency value, falling short of a predetermined frequency gradient, that is to say when the frequency drops particularly sharply, is also taken into consideration. In principle, both criteria can also be combined by way of, for example, tripping first taking place when a predetermined frequency value is fallen short of and also a predetermined frequency gradient has been fallen short of.

For testing the underfrequency mode, the test frequency function prespecifies the frequency profile as grid frequency in the wind power installation and the test starts when this frequency profile falls short of the predetermined frequency value in order to trip the underfrequency mode for testing purposes in this way. It goes without saying that the predetermined frequency gradient can correspondingly also be taken into account for tripping purposes here.

Therefore, the frequency profile is prespecified instead of the measured frequency, this as such not yet having to lead to tripping of the underfrequency mode. However, in general, the frequency profile of the test frequency function is selected such that it immediately falls short of the predetermined frequency value in order to trip the underfrequency mode in this way.

A central farm controller is preferably provided for controlling the wind farm. This central farm controller synchronously transmits the start signal to all participating wind power installations in order to trigger the farm test mode in this way. Therefore, a predetermined frequency profile is then used in the farm test mode and taken into consideration instead of the measured grid frequency, and the process of taking this into consideration is synchronously started at the same time for all wind power installations by the tripping command. Therefore, all wind power installations then also synchronously run through the respective frequency profile. If this frequency profile falls short of the predetermined frequency value, for example after one second, the underfrequency mode is then synchronously started respectively in all wind power installations as a result and is also substantially synchronously run through in each wind power installation, or a test is carried out thereby as to whether this has taken place. It goes without saying that falling short of the predetermined frequency gradient could equally also lead to synchronous tripping for all wind power installations synchronously.

A test method for testing a wind farm for a frequency event, in particular for an underfrequency event, is proposed, wherein, in a farm test mode for testing a behavior of the wind farm in the case of a frequency event or underfrequency event, the wind power installations each change to their frequency mode or underfrequency mode, wherein the frequency modes or underfrequency modes of the wind power installations are, however, coordinated by way of test frequency values of a test frequency profile being transmitted to all participating wind power installations. This preferably takes place in real time in order to emulate the same grid frequency profile for all participating wind power installations in this way.

The same frequency modes or underfrequency modes which have already been described above can be tested hereby, wherein the wind power installations are coordinated in a different manner for testing the wind farm here. According to this proposal, synchronous testing of all participating wind power installations takes place by way of said participating wind power installations continuously receiving frequency values to be tested, particularly from a central control unit. To this end, particular care should be taken that these test frequency values always reach the wind power installations synchronously. This preferably takes place in real time, but it is possible for this not to take place in real time, provided that the same test frequency values respectively always arrive at the individual wind power installations at the same time.

It has therefore been found that, by observing this synchronicity and in the process optionally observing different propagation times, it is also possible for test frequency values to be synchronously present at the respective wind power installations in order to synchronously use the underfrequency modes for testing the entire wind farm in this way.

It has also been found that the level of complexity for data transmission which is possibly high here can be justified in order to be flexible in respect of prespecifying the respective frequency profiles for testing the underfrequency modes and to be able to prespecify frequency profiles for testing purposes in a flexible manner from a central point, particularly the central control unit of the wind farm.

According to one embodiment, it is proposed that the test frequency values are interpolated in each participating wind power installation in order to obtain a coherent frequency profile of the grid frequency to be emulated in this way. As a result, it is not necessary to transmit a test frequency value to all wind power installations at each measurement time at which, up until now, the grid frequency was recorded and taken into consideration. Therefore, it can suffice to transmit test frequency values at a considerably lower data rate and to obtain the values therebetween by interpolation. In particular, the problem that real-time transmission of a test frequency value at every sampling time of the controller, which controls the underfrequency mode, would make a very high data rate necessary and possibly would be extremely costly could be addressed as a result.

The test frequency profile is preferably transmitted to the wind power installations by a central farm control unit and, in addition or as an alternative, the test frequency profile is prespecified by the central farm control unit in order to match the test frequency profile to profiles of the grid frequency which are to be tested. As a result, it is possible to centrally control this test using a central farm control unit. As a result, it is even possible to take into account the established behavior, that is to say particularly the established power values, and possibly match them to the frequency profile. As a result, a reaction of the electrical supply grid to an underfrequency behavior of said kind of the farm could also be emulated as a result.

A further embodiment proposes that the test frequency profile is adapted depending on a resulting behavior of the wind power installation. This is proposed in particular during the test farm mode too. Therefore, said test frequency profile can react to the behavior of the wind power installation and therefore to the behavior of the wind farm overall. The test of the underfrequency event can therefore be adapted even more realistically.

This adjustment preferably takes place depending on a sum of all additional electrical powers which are fed into the electrical supply grid from rotational energy of the rotor. Therefore, the amount of power which has been additionally generated and fed in overall in the wind farm in this farm test mode is taken into consideration. The emulated frequency profile can then be adapted depending on the connected electrical supply grid, particularly depending on the properties of a common grid connection point. A property of said kind of the common grid connection point can be, for example, a short-circuit current ratio at the grid connection point or a constant of inertia of a quantity of synchronous generators which are directly coupled to the electrical supply grid, particularly in a predetermined section of the electrical supply grid.

A wind farm is also proposed, in which wind farm a test method according to at least one above-described embodiment is implemented.

A wind power installation is also proposed, which wind power installation has a rotor with one or more rotor blades in order to generate wind power from wind and to feed said wind power into an electrical supply grid. This wind power installation has a frequency mode, in particular an underfrequency mode, which changes the fed-in power depending on the grid frequency when a frequency event or an underfrequency event occurs, in particular temporarily obtains electrical power from rotational energy of the rotor, which electrical power is additional to the wind power, and feeds said additional electrical power into the electrical supply grid.

The wind power installation is therefore configured, in response to a start signal, to use a predetermined test frequency function as the emulated grid frequency in order to test the frequency mode in this way. Therefore, said wind power installation can simultaneously start and run through the underfrequency mode together with other wind power installations, specifically also with the same test frequency function, when the other installations likewise receive the same start signal or receive a start signal simultaneously, and use the same test frequency function. In this case, the start signal can be received as such and, when received, start the use of the test frequency function immediately or after a predetermined waiting time. The start signal can also be generated or tripped depending on a time start command, which prespecifies a start time; in particular, the time start command or the start signal is received by the wind power installation from a central control unit of a wind farm. Accordingly, it is proposed that the wind power installation has been constructed or is constructed in a wind farm.

As an alternative, the wind power installation is configured to receive test frequency values of a test frequency profile in order to emulate a grid frequency profile based thereon. According to this alternative, the wind power installation therefore receives the intended test frequency profile or at least support points thereof directly, and then uses this as the emulated grid frequency profile. A plurality of wind power installations can also simultaneously run through a frequency mode or underfrequency mode as a result, specifically based on the same test frequency profile when this is also synchronously transmitted to other wind power installations.

A wind power installation of said kind is preferably configured to be erected or operated in an above-described wind farm; in particular for carrying out a test method according to at least one above-described embodiment for testing a behavior of a wind farm. In particular, said wind power installation behaves there like one of the plurality of wind power installations which are used for a test method of said kind.

### BRIEF DESCRIPTION OF THE SEVERAL VIEWS OF THE DRAWINGS

The invention will be explained in more detail by way of example on the basis of embodiments with reference to the accompanying figures.

FIG. 1 schematically shows a perspective illustration of a wind power installation.

FIG. 2 shows a schematic illustration of a wind farm.

FIG. 3 shows a wind farm, where a schematic structure for illustrating the manner of operation of an underfrequency mode in a test method is shown in respect of one of the wind power installations.

FIG. 4 shows a frequency profile of a test frequency function and illustrates the change in a profile duration.

FIG. 5 schematically shows a frequency profile of a test frequency function and illustrates the change in an amplitude factor.

### DETAILED DESCRIPTION

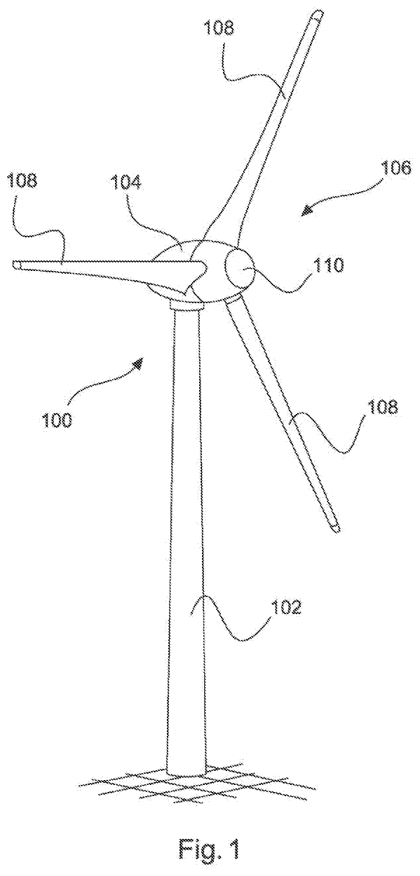

FIG. 1 shows a wind power installation 100 having a tower 102 and a nacelle 104. A rotor 106 having three rotor blades 108 and a spinner 110 is arranged on the nacelle 104. The rotor 106 is set in a rotary motion by the wind during operation and in this way drives a generator in the nacelle 104.

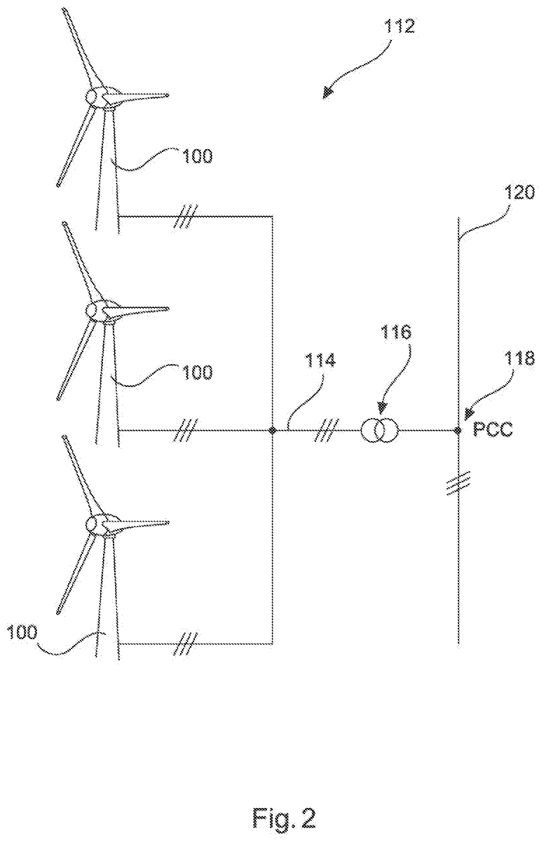

FIG. 2 shows a wind farm 112 having, by way of example, three wind power installations 100 which can be identical or different. The three wind power installations 100 are therefore representative of basically an arbitrary number of wind power installations of a wind farm 112. The wind power installations 100 provide their power, specifically in particular the generated current, via an electrical farm grid 114. In this case, the respectively generated currents or powers of the individual wind power installations 100 are added up and usually a transformer 116 is provided, which transformer steps up the voltage in the farm so as to then feed power into the supply grid 120 at the feed point 118, which is also referred to generally as a PCC. FIG. 2 is merely a simplified depiction of a wind farm 112 which does not show a controller, for example, even though a controller is of course present. It is also possible for the farm grid 114 to be of different design, for example by way of there also being a transformer at the output of each wind power installation 100, to cite just one other exemplary embodiment for example.

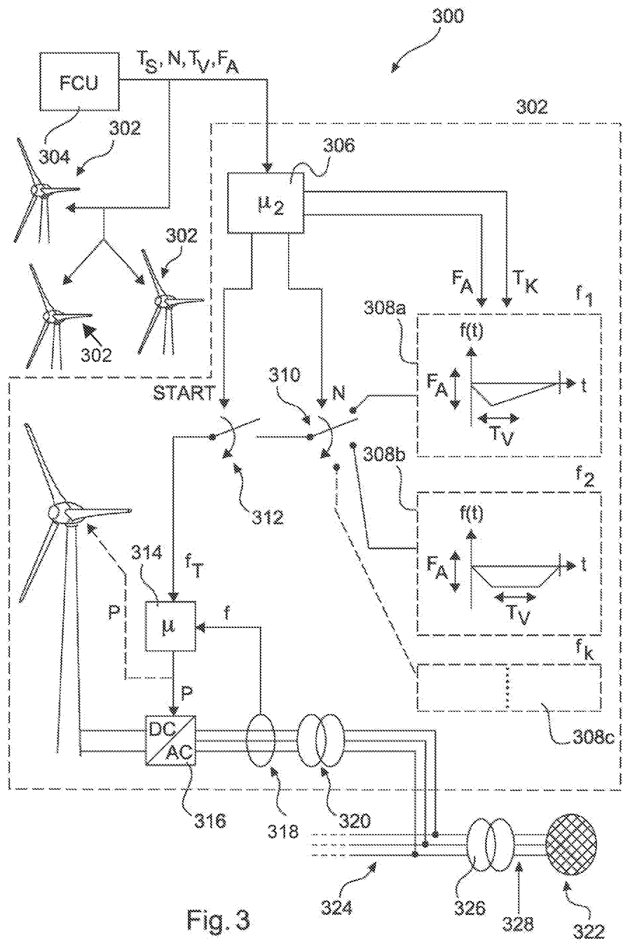

FIG. 3 shows a wind farm 300 which corresponds, in principle, to FIG. 2. Both FIGS. 2 and 3 are, in this respect, each schematic illustrations of the wind farm. The wind farm 300 of FIG. 3 shows four wind power installations 302 which, by way of example, also represent further wind power installations. One of the wind power installations 302 shown comprises all elements of the structure shown within the frame indicated using dashed lines, and therefore the frame indicated using dashed lines is provided with reference symbol 302. In principle, provision is also made for the other wind power installations 302 to have the same or an identical structure, wherein details thereof can differ.

A farm controller 304 which can actuate all wind power installations 302 of the wind farm 300 is provided in the entire wind farm 300. Only a few examples of actuation variables which are transmitted and exchanged are shown, these being used to explain the present disclosure. Other and further data can also be transmitted and it is not absolutely necessary for all variables shown to be transmitted either.

In the example shown, the tripping or trigger command T_{S}, the selection signal N, the step duration T_{K} and the amplitude factor F_{A} are transmitted. These elements can also be transmitted in a common test signal which can also be referred to as the start signal. This transmission takes place to each of the wind power installations 302. There, said elements are transmitted to the coordination controller 306. This coordination controller or coordination control device coordinates the planned test and forwards the corresponding commands to the respective elements.

In order to carry out the test method, particularly in the farm test mode, a plurality of test frequency functions 308a, 308b and 308c which each have a frequency profile as the test function are stored in each wind power installation 302. These test frequency functions are also designated f₁, f₂ and fₖ there. The last test frequency function 308c or fₖ is merely indicated and symbolizes that any desired number of test frequency functions can be stored in principle. However, a few test frequency functions, such as two or three test frequency functions for example, usually suffices.

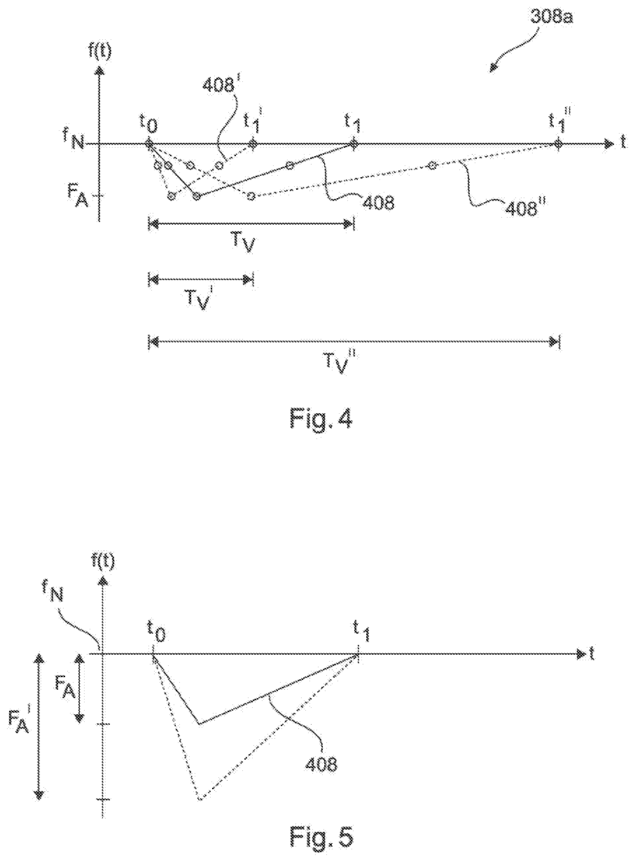

Each of these test frequency functions 308a to 308c can also be set in respect of their profile duration T_{V}=k*T_{K}, determined from the step duration T_{K} and the defined step number k, and in respect of their amplitude factor F_{A}. To this end, these functions contain these parameters and the change is merely indicated in FIG. 3. The significance of the profile duration T_{V} and also of the amplitude factor F_{A} is illustrated in FIGS. 4 and, respectively, 5, which will be explained in more detail later.

In this case, the selection signal N defines which of the stored test frequency functions 308a to 308c or the stored frequency profiles are selected for testing purposes. This is illustrated by a selector switch 310 which, however, can also be implemented in a different way, such as by a software selection, that is to say by programming, for example. In any case, a selection is made between one of the test frequency functions 308a to 308c depending on the selection signal N.

In order to then also start the test, the tripping command T_{S} is provided. Said tripping command is converted into a start command in the coordination controller 306, which start command can start the test using the start switch 312. The start switch 312 is also to be understood particularly symbolically here.

The process proceeds particularly such that the installation controller 314 receives, with the start command, that is to say with the symbolic switching on of the start switch 312, the frequency profile of the test frequency function 308a, 308b or 308c in question as the frequency to be taken into account and adjusts to it for the purpose of this test.

In principle, the installation controller 314 controls the inverter 316 shown by way of example. Said installation controller passes, amongst other things, a setpoint value for the active power P to said inverter for this purpose. In principle, this setpoint value of the active power P can also be transmitted to other control devices of the wind power installation, this being indicated by the dashed line to the nacelle of the wind power installation. In any case, the installation controller 314 controls the inverter 316, amongst other things, depending on the frequency f which is detected by means of the frequency measuring device 318. This frequency detection can take place on the shown side of the transformer 320, or else in a region in the direction of the farm grid 324. In any case, the grid frequency f of the electrical supply grid 322, that is to say the AC voltage in the electrical supply grid 322, is detected by the frequency measuring device 318 as a result. It goes without saying that further variables can also be detected, however said further variables are not illustrated here.

If a test is now started in order to test the underfrequency mode of the wind power installation 302, the installation controller 314 now takes into account, with the start command, that is to say with the symbolic closing of the start switch 312, the emulated test frequency f_{T} instead of the grid frequency f.

It goes without saying that the grid frequency f and also the phase position and further variables are also furthermore detected in order to technically correctly actuate the inverter 316. However, the test frequency f_{T} is now used for prespecifying the active power P.

As soon as the frequency profile of the test frequency functions 308a, 308b or 308c is concluded, that is to say after the profile duration T_{V} elapses, this test situation is concluded again and the installation controller 314 then uses the grid frequency f again.

The functionality does not depend on whether an inverter 316 is used or power is fed into the electrical supply grid 322 by the wind power installation 302 in some other way. In principle, provision is also made for each wind power installation 302 to initially feed power into the farm grid 324, which is merely indicated here. The further farm grid transformer 326 shown can identify the common grid connection point 328 of the wind farm 300. However, a wind farm which comprises a plurality of wind farms and/or feeds power into the electrical supply grid via a plurality of grid connection points can also be used and tested.

FIG. 4 shows a frequency profile of a test frequency function, for example the test frequency function 308a, as indicated in FIG. 3.

Its frequency profile 408 begins at time to at rated frequency f_{N}. The frequency then quickly drops down to the value F_{A} which can be, for example, 99 percent of the rated frequency f_{N}. The frequency then rises again until time t₁ and there reaches the rated frequency f_{N} again. This is merely an illustrative profile and the type of frequency profile can also be configured differently, as is indicated for the test frequency function 308b of FIG. 3 for example.

In any case, the frequency profile 408 shown is predetermined for the profile duration T_{V}. If this profile duration is concluded, the test overall and therefore the underfrequency mode and therefore the farm test mode are also to be concluded.

However, there is now the possibility to compress or to extend the frequency profile by way of a shorter profile duration T′_{V} or a longer profile duration T″_{V} being selected. This takes place by determining a step duration T_{K}. The profile duration (T_{V}) is then given by the step number k, the values of the stored frequency profile and the step duration (T_{K}) in accordance with the formula T_{V}=k*T_{K}. In FIG. 4, frequency values are marked as small circles in the frequency profiles 408, 408′ and 408″ for illustrative purposes. In this simplified example, five frequency values are provided and each of the three frequency profiles 408, 408′ and 408″ has the same five frequency values, but at different times. Here, the number of five frequency values has been selected only for illustrative purposes, wherein it is proposed for the actual implementation to select a significantly higher number.

A change of said kind in the profile duration therefore leads to the end time t₁ being shifted, specifically to the time t′₁ or t″₁ shown. The correspondingly changed profile of the frequency is illustrated using dashed lines in FIG. 4.

With the change in the end time, that is to say t′₁ or t″₁, the duration of the test is also changed. The actual underfrequency mode, that is to say the prespecification of an increased active power P, can be tripped solely depending on the frequency values in this case. That is to say, if the critical frequency, that is to say either the measured grid frequency for the emulated frequency f_{T}, drops below a predetermined value, the underfrequency mode is tripped.

It should also be noted that the frequency profile does not necessarily have to begin with the rated frequency f_{N}. However, the grid frequency is often approximately at this value. According to one variant, the frequency which is currently present at that moment can be used instead of the rated frequency f_{N}.

Analogously, a corresponding frequency profile is stored for testing another frequency event, such as an overfrequency event or a frequency oscillation for example.

FIG. 5 likewise shows a test frequency function with a frequency profile 408 in accordance with FIG. 4. FIG. 5 now illustrates that the frequency profile 408 can also be changed in the amplitude direction by changing the amplitude. To this end, the amplitude factor F_{A} can be reduced or increased, and FIG. 5 shows, by way of example, an increase to the increased amplitude factor F′_{A}. Instead of a direct prespecification of the amplitude by the amplitude factor F_{A}, it is also possible to actually use the amplitude tractor F_{A} as a factor which assumes the value 1 when the amplitude of the stored frequency test function or of the stored frequency profile is intended to be maintained, and otherwise positive values above or below 1 can be used for changing purposes. It goes without saying that, in principle, it is also possible to provide and add or subtract an offset.

The disclosure therefore proceeds from the following assumption. Particularly in the case of underfrequency events in the grid, some wind power installations make a contribution to frequency stability by way of a brief increase in the power which is fed into the grid. This functionality is implemented in the wind power installation controller since a rapid reaction is required when passing through specific frequency measurement values. Testing of this function is possible in the case of wind power installations in the field only by way of a virtual frequency value, which differs from the actually measured frequency, specifically usually the grid frequency, being prespecified in the controller of the wind power installation. The reason for this is that the actual grid frequency cannot or must not be easily manipulated.

The function of providing an increased power in the case of a drop in frequency, which function is also referred to as inertia emulation, is becoming increasingly widespread in specific energy systems. As a result, the behavior of entire wind farms in the case of an underfrequency event is increasingly relevant. Since simultaneous tripping of the test function in numerous wind power installations can be problematical, or a very accurate time synchronization of the tripping would be required for test purposes, there is the need for centrally prespecified tripping of the test function in each wind power installation by means of data communication.

Central farm controllers are already installed in a large number of wind farms. Said central farm control units are connected to all wind power installations in a farm via communications lines and transmit active and reactive power setpoint values and also other control signals to the wind power installations at regular intervals during normal operation. However, the speed of data communication is usually not high enough or can be very expensive in order to configure rapid active power regulation such that it meets the requirements in the case of a rapidly occurring underfrequency event.

In order to nevertheless render possible central tripping of at least one test function, it is proposed that the wind farm control device sends a tripping signal to all wind power installations in a wind farm within a very small time window, which tripping signal can also be referred to as a start signal which results in virtually simultaneous tripping of the function inertia emulation as the function of providing an increased power in the case of a drop in frequency, on the basis of a virtual frequency signal in all wind power installations. For this purpose, it is proposed according to one embodiment that the tripping signal or start signal contains the following two items of information in this case, specifically:
a command for tripping the inertia emulation function on the basis of a virtual frequency profile which is stored in the controller; and
a selection signal in order to select one frequency profile for the test situation from various frequency profiles which are stored in the wind power installation controller.

In this case, all wind power installations receive the same tripping signal and therefore execute the test on the basis of the same stored frequency profile and at a virtually identical tripping time. Therefore, repeated tripping of the function with the purpose of measurement data collection is possible in a simple manner by operating the FCU.

The possibility of influencing the frequency profile by changing the time base of the stored frequency profile by the central farm control is proposed according to a further embodiment. In addition to the possibility of choosing between one of the predefined or stored frequency profiles, there is also the option of varying the time base, with which the test profile takes place, on the part of a central controller, particularly on the part of a central farm controller.

According to one embodiment, the time base, which is also synonymously referred to as the profile duration, in the installation is set by default at 100 ms and can be set, particularly by the central farm control device, between 10 ms and 1000 ms with a resolution of 10 ms. Therefore, it is possible to allow the curve profile, that is to say the frequency profile, to proceed up to 10 times more quickly and also to 10 times more slowly.

Therefore, simultaneous tripping of the inertia emulation test function, which is implemented on each wind power installation controller and can also be referred to as the underfrequency mode, is rendered possible for all wind power installations in a wind farm.

As a result, virtually simultaneous tripping of the inertia emulation test function in a large number of different wind power installations is achieved. This renders possible a compliance test or collection of test data for development purposes for a wind farm in a simple manner. In particular, wind farm tests of underfrequency reactions are provided, and the wind farm tests use the superordinate active power controller of the wind power installations.

The proposed method uses a test function which is used in each individual wind power installation. This test function starts a stored simulated frequency event, specifically an underfrequency curve, at the installation level. The corresponding power is then output at the installation level depending on the parameterization of the inertia emulation.

To this end, it is proposed that the central farm controller serves as the tripping device for the inertia test function at the farm level. For this purpose, the farm control device provides a menu in which the tripping of the inertia test function is triggered at the installation level. In this case, each installation, which is connected to a data bus of the central farm controller, starts the installation-internal test frequency curve.

To this end, a stored frequency curve is selected in the controller of each wind power installation. To this end, a numerical value, for example from 1 to 99, can be selected. In this case, it may suffice for, for example, only 3 curves to be stored, so that it is then possible to choose from amongst the numbers 1, 2 and 3.

The option of compressing or expanding or extending the stored frequency curve by means of a change in the profile duration, in particular by means of the change in a step duration, is proposed. For this purpose, provision can be made for the numerical value 0 to mean using a stored standard value for the step duration sampling time step, which stored standard value can be 100 ms or 200 ms for example. It is proposed that the minimum value is 10 ms and the maximum value is 1000 ms.

Each installation is sent a bit signal, which executes the test function at the installation level, that is to say in each wind power installation, by way of a start signal, which can also be referred to as “start”, in the data bus of the central farm controller.

However, the central farm controller cannot directly trip the inertia function at the installation level, but rather only a test of the inertia function. The regulation of a central farm controller is otherwise not influenced.

The input of a service code is preferably required for activating this test, in order to prevent misuse.

As an alternative, rapid power frequency regulation of a wind farm can be carried out, optionally with power setpoint values from the wind farm control device, so that a virtual frequency profile is stored only in the wind farm control device. Correspondingly rapid and secure data transmission within the wind farm has to be ensured for this purpose.

1. A method for testing a behavior of a wind farm in response to a frequency event, the wind farm including a plurality of wind power installations which feed electrical power into an electrical supply grid, each wind power installation of the plurality of wind power installations has a rotor with one or more rotor blades and generates wind power from wind and feeds the wind power into the electrical supply grid, which has a grid voltage and a grid frequency, the method comprising:
temporarily changing a fed-in power of a respective frequency mode of each wind power installation of the plurality of wind power installations based on the grid frequency when the frequency event occurs;
changing the respective frequency mode of each wind power installation of the plurality of wind power installations in a farm test mode for testing the behavior of the wind farm in the frequency event; and
testing frequency modes of the plurality of wind power installations participating in the test at the same time to test the behavior of the wind farm, wherein the frequency modes each have a respective test frequency function that emulates the frequency event, testing the frequency modes including:
starting the frequency modes simultaneously using a common time start command; and
setting an identical test frequency function for each wind power installation of the plurality of wind power installations.

2. The method as claimed in claim 1, comprising:
storing, by each wind power installation of the plurality of wind power installations, the respective test frequency function; and wherein the respective frequency mode is an underfrequency mode in which both the wind power generated from the wind and the electrical power generated from rotational energy of the rotor are fed into the electrical supply grid when an underfrequency event occurs.

3. The method as claimed in claim 1, comprising:
storing, by each wind power installation of the plurality of wind power installations, a plurality of test frequency functions that are different from each other and that correspond to test frequency functions of other participating wind power installations of the plurality of wind power installations; and
selecting, in the farm test mode, one test frequency function from the plurality of test frequency functions, wherein the same test frequency function is selected in each wind power installation of the plurality of wind power installations.

4. The method as claimed in claim 1, comprising:
starting the test, in the farm test mode, by at least:
transmitting a selection signal to each wind power installation of the plurality of wind power installations for selecting the respective test frequency function; and
transmitting a trigger command synchronously transmitted to each wind power installation of the plurality of wind power installations for synchronously triggering tripping the respective frequency mode of each wind power installation.

5. The method as claimed in claim 4, wherein:
each respective test frequency function specifies a respective frequency profile over a predeterminable profile duration;
each wind power installation of the plurality of wind power installations, in the respective frequency mode, generates a change in power depending on a frequency, wherein the respective frequency profile of the respective test frequency function is used for testing the respective frequency mode; and
each wind power installation of the plurality of wind power installations, in a respective underfrequency mode, generates an increase in the power depending on the frequency, wherein the respective frequency profile of the test frequency function is used for testing the underfrequency mode.

6. The method as claimed claim 5, comprising:
setting an amplitude factor to set an amplitude of the respective test frequency function or of the respective frequency, wherein in the farm test mode, amplitude factors of the plurality of wind power installations are set to identical values.

7. The method as claimed claim 2, comprising:
in the underfrequency mode, feeding the electrical power generated from the rotational energy of the rotor into the electrical supply grid when the grid frequency is below a predetermined frequency value;
controlling the electrical power generated from the rotational energy of the rotor based on a profile of the grid frequency;
storing a control specification, in each the wind power installation of the plurality of wind power installations for controlling the electrical power generated from the rotational energy of the rotor; and
triggering the underfrequency mode automatically the wind power installation when the grid frequency falls below the predetermined frequency value or falls below a predetermined frequency gradient, and wherein for testing the underfrequency mode, the respective test frequency function specifies a frequency profile as the grid frequency in the wind power installation.

8. The method as claimed in claim 1, wherein a central farm controller is provided for controlling the wind farm, and the central farm controller synchronously transmits a start signal to the plurality of wind power installations to trigger the farm test mode.

9. A test method for testing a behavior of a wind farm in response to a frequency event, the wind farm having a plurality of wind power installations that respectively feed electrical power into an electrical supply grid, each wind power installation of the plurality of wind power installations has a rotor with one or more rotor blades and generates respective wind power from wind and feeds the respective wind power into the electrical supply grid, which a grid voltage and a grid frequency, the test method comprising:
temporarily changing a respective fed-in power of a respective frequency mode of each wind power installation of the plurality of wind power installations based on the grid frequency when the frequency event occurs;
changing the respective frequency mode of each wind power installation of the plurality of wind power installations in a farm test mode for testing the behavior of the wind farm in the frequency event; and
testing frequency modes of the plurality of wind power installations, at the same time to test the behavior of the wind farm in this way, wherein the frequency modes each have a respective test frequency function that emulates the frequency event, and testing the frequency modes is coordinated using test frequency values of a test frequency profile transmitted to the plurality of wind power installations to emulate the same grid frequency profile for the plurality of wind power installations.

10. The test method as claimed in claim 9, comprising:
interpolating the test frequency values in each wind power installation to obtain a coherent frequency profile for emulating the grid frequency; and
transmitting frequency-dependent power values for use by the plurality of wind power installations in the farm test mode, wherein each wind power installation has a respective underfrequency mode as the respective frequency mode in which electrical power from rotational energy of the rotor in addition to the wind power is fed into the electrical supply grid when an underfrequency event occurs.

11. The test method as claimed in claim 9, comprising:
transmitting, by a central farm controller, the test frequency profile to the plurality of wind power installations; and
specifying, by the central farm controller, the test frequency profile to match the test frequency profile to profiles of the grid frequency to be tested.

12. The test method as claimed in claim 9, comprising:
configuring the test frequency profile based on a resulting behavior of the plurality wind power installations during the farm test mode; and
changing the test frequency profile based on a sum of additional electrical power fed into the electrical supply grid from the rotational energy of the rotor.

13. A wind farm operative to perform a test method for testing a behavior of the wind farm in response to a frequency event, comprising:
a plurality of wind power installations, each wind power installation of the plurality of wind power installations including:
a rotor with one or more rotor blades and generating wind power from wind, wherein:
each wind power installation of the plurality of wind power installations feeds the wind power into an electrical supply grid that has a grid voltage and a grid frequency,
each wind power installation of the plurality of wind power installations has a respective frequency mode for temporarily changing fed-in power depending on the grid frequency when a frequency event occurs,
each wind power installation of the plurality of wind power installations is operative to change the respective frequency mode in a farm test mode for testing the behavior of the wind farm in case of the frequency event,
frequency modes of the plurality wind power installations are tested at the same time,
the frequency modes each use a respective test frequency function which emulates the frequency event,
the plurality of wind power installations receive a common start signal simultaneously,
an identical test frequency function is configured for the plurality wind power installations, and
test frequency values of a test frequency profile are transmitted to the plurality of wind power installations to emulate the same grid frequency profile for the plurality of wind power installations.

14. (canceled)

15. A wind power installation, comprising:
a rotor having one or more rotor blades to generate wind power from wind and to feed the wind power into an electrical supply grid, wherein the electrical supply grid has a grid voltage and a grid frequency, and the wind power installation has a frequency mode which temporarily changes the fed-in power based on the grid frequency when a frequency event occurs, wherein the wind power installation is configured to:
receive a start signal;
in response to receiving the start signal, use a predetermined test frequency function as an emulated grid frequency to test the frequency mode; and
to receive test frequency values of a test frequency profile to emulate a grid frequency profile based on the test frequency values.

16. The wind power installation as claimed in claim 15, configured for use in a wind farm.

17. The method as claimed in claim 4, comprising:
transmitting the selection signal and the trigger command together in a start signal.

18. The method as claimed in claim 5, wherein:
the predeterminable profile duration is set to extend or to compress the respective test frequency function or the respective frequency profile; and
in the farm test mode, profile durations of the plurality of wind power installation are set to identical values using a start signal, wherein the predeterminable profile duration is subdivided into a plurality of identical sampling time steps having a step duration that identifies a duration of each sampling time step and a step number that indicates a number of the plurality of identical sampling time steps of the profile duration.
